(19) United States
(12) Patent Application Publication
(10) Pub. No.: US 2024/0243047 A1
(43) Pub. Date: Jul. 18, 2024

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Hung-Chun Cho, Hsinchu (TW); Wei-Chih Chen, Hsinchu (TW); Po-Han Wang, Hsinchu (TW); Yu-Hsiang Hu, Hsinchu (TW); HUNG-JUI KUO, Hsinchu (TW)

(73) Assignee: Taiwan Semiconductor Manufacturing Company, Ltd., Hsinchu (TW)

(21) Appl. No.: 18/097,970

(22) Filed: Jan. 17, 2023

(51) Int. Cl. H01L 23/498; H01L 21/48; H01L 21/56; H01L 23/31

(52) U.S. Cl. CPC H01L 23/49822; H01L 21/4857; H01L 21/568; H01L 23/3128; H01L 23/49811; H01L 23/49894; H01L 24/16; H01L 2224/16227

(57) ABSTRACT

A semiconductor package includes a semiconductor component, a package body, a first RDL structure and an insulation layer. The package body surrounds the semiconductor component and has a first package surface. The first RDL structure is formed on the first package surface of the package body. The insulation layer is formed on the first RDL structure and includes an insulation body, a plurality of recessed portions and a plurality of voids, wherein the insulation body has a first insulation surface, the recessed portions are recessed with respect to the first insulation surface and form a pattern, and the voids are embedded in the insulation body.

### BACKGROUND

The semiconductor package needs to mark a laser marking pattern on a material of the package for showing product information, and the laser marking pattern is required to be easily recognized. Thus, obtaining recognition feasibility for the laser marking pattern is one of the goals of those skilled in the art.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a top view of a semiconductor package according to an embodiment of the present disclosure;

FIG. 1B illustrates a schematic diagram of a cross-sectional view of the semiconductor package of FIG. 1A in a direction 1B-1B′;

FIG. 1C illustrates a diagram of a relationship between a wavelength and an absorbance of the dye of FIG. 1B;

FIG. 1D illustrates a diagram of a relationship between a wavelength and an absorption coefficient of the insulation layer of FIG. 1B;

FIG. 2 illustrates a schematic diagram of a cross-sectional view of the semiconductor package according to another embodiment of the present disclosure;

FIG. 3 illustrates a schematic diagram of a cross-sectional view of the semiconductor package according to another embodiment of the present disclosure;

FIGS. 4A to 4J illustrate schematic diagrams of a manufacturing method of the semiconductor package of FIG. 1B;

FIGS. 5A to 5J illustrate schematic diagrams of a manufacturing method of the semiconductor package of FIG. 2; and

FIGS. 6A to 6J illustrate schematic diagrams of a manufacturing method of the semiconductor package of FIG. 3.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

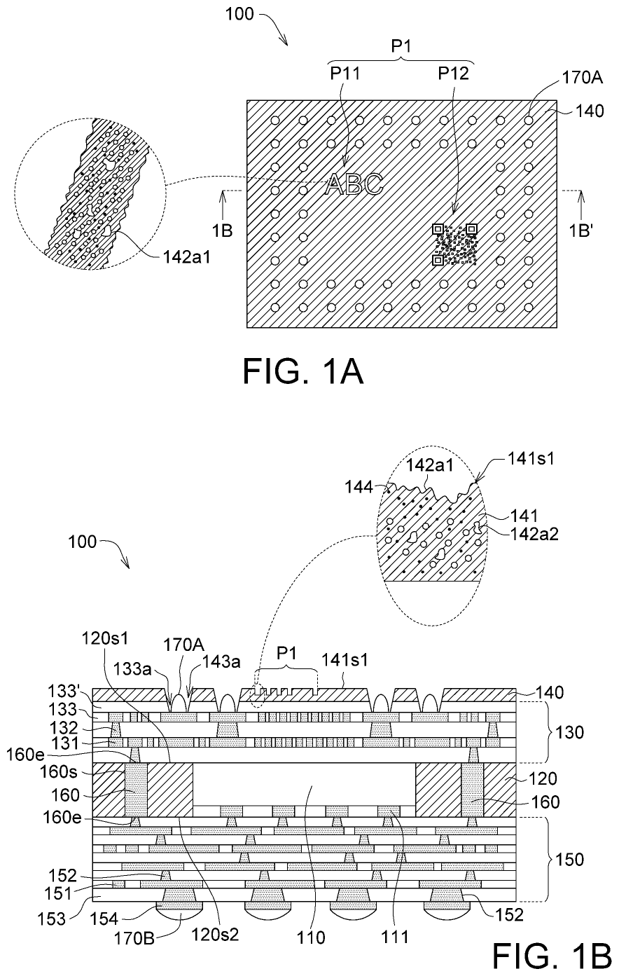

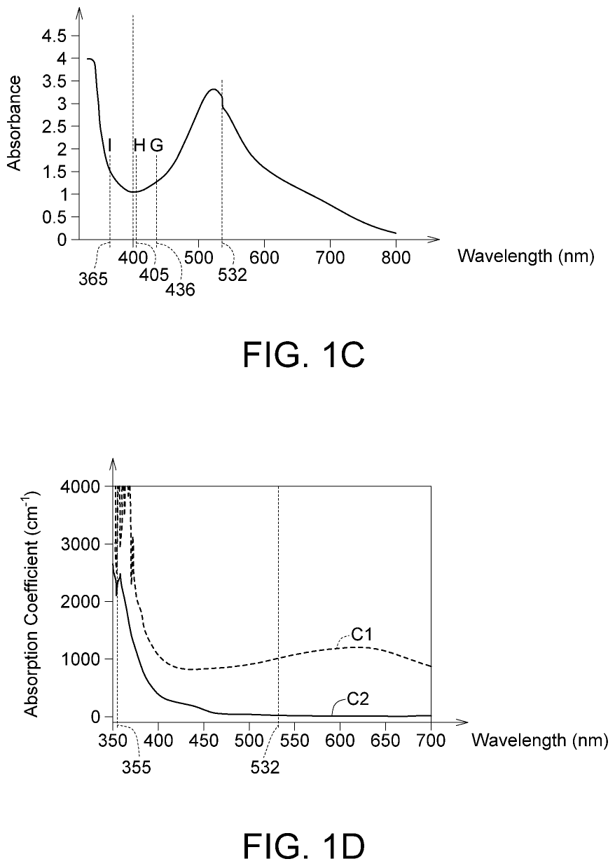

Referring to FIGS. 1A to 1D, FIG. 1A illustrates a schematic diagram of a top view of a semiconductor package 100 according to an embodiment of the present disclosure, FIG. 1B illustrates a schematic diagram of a cross-sectional view of the semiconductor package 100 of FIG. 1A in a direction 1B-1′, FIG. 1C illustrates a diagram of a relationship between a wavelength and an absorbance of the dye of FIG. 1i, and the FIG. 1D illustrates a diagram of a relationship between a wavelength and an absorption coefficient of the insulation layer 140 of FIG. 1B.

As illustrated in FIGS. 1A and 1B, the semiconductor package 100 includes at least one semiconductor component 110, a package body 120, a first redistribution layer (RDL) structure 130, an insulation layer 140, and a second RDL structure 150, at least one conductive via 160, at least one first conductor contact 170A and at least one second conductor contact 170B.

As illustrated in FIGS. 1A and 1B, the package body 120 surrounds the semiconductor component 110 and has a first package surface 120s1. The first RDL structure 150 is formed on the first package surface 120s1 of the package body 120. The insulation layer 140 is formed on the first RDL structure 130 and includes an insulation body 141, a plurality of recessed portions 142a1 and a plurality of voids 142a2, wherein the insulation body 141 has a first insulation surface 141s1, the recessed portions 142a1 are recessed with respect to (or from) the first insulation surface 141s1 and form a pattern P1, and the voids 142a2 are embedded in the insulation body 141. Due to the recessed portions 142a1, the pattern P1 is visible and recognizable.

As illustrated in FIG. 1A, the pattern P1 may indicate a product information. The pattern P1 includes a first pattern P11 and a second pattern P12, wherein the first pattern P11 is, example, a symbols, alphabet, numbers or a pattern including a straight line, a curved line or a combination thereof. The second pattern P12 is, for example, a date code. The pattern P1 may be formed by using, for example, laser marking, and may be recognized by an optical defect inspection device (for example, ICOS provided by KLA-Tencor Corporation). Furthermore, the semiconductor package 100 may pass the visual inspection, data code inspection of ICOS and/or OCR inspection of ICOS.

As illustrated in FIG. 1B, the semiconductor component 110 is, for example, a SoC (system on chip). The semiconductor component 110 includes a plurality of conductive contact 111, and the conductive contact 111 are disposed on and electrically connected to the second RDL structure 150, and the semiconductor component 110 may electrically connect to the first RDL structure 130 through the second RDL structure 150 and the conductive via 160.

The package body 120 is, for example, a molding compound. The package body 120 may be formed of a molding material including, for example, a Novolac-based resin, an epoxy-based resin, a silicone-based resin, or another suitable encapsulant. Suitable fillers also may be included, such as powdered SiO2. The molding material may be applied using any of a number of molding techniques, such as compression molding, injection molding, or transfer molding.

As illustrated in FIG. 1B, the first RDL structure 130 includes at least one first conductive trace layer 131, at least one first conductive via layer 132 and at least one first dielectric layer 133, wherein the adjacent two first conductive trace layers 131 are separated from one of the first dielectric layers 133, and the adjacent two first conductive trace layers 131 may be electrically connected by one of the first conductive via layers 132. In addition, the first conductive trace layer 131 and the first conductive via layer 132 may be formed of, a material including, for example, copper, etc., and the first dielectric layers 133 may be formed of, a material including, for example, polyimide (PI), etc. In an embodiment, the conductive trace layer 131 has a thickness ranging 4 micrometers (μm) to 8 μm, for example, 4 μm, 5 μm, 6 μm, 7 μm, 8 μm etc., or more greater, or smaller.

As illustrated in FIG. 1B, the insulation layer 140 is formed on the outermost first dielectric layers 133′ of the first RDL structure 130. The insulation layer 140 has at least one insulation through-hole 143a and the outermost first dielectric layers 133′ has at least one dielectric through-hole 133a overlaps the insulation through-hole 143a, wherein the insulation through-hole 143a and the dielectric through-hole 133a are configured for receiving the first conductor contact 170A.

As illustrated in FIG. 1B, the insulation layer 140 further includes a dye doped in the insulation body 141. The insulation body 141 may be formed of, a material including, for example, PI, Benzocyclobutene (BCB), Polybenzoxazole (BPO) or epoxy. In an embodiment, the insulation body 141 may be formed of a material the same as that of the first dielectric layer 133. In addition, the In an embodiment, the insulation body 141 has a thickness ranging 8 μm to 12 μm, for example, 8 μm, 9 μm, 10 μm, 11 μm, 12 μm etc., or more greater, or smaller.

As illustrated in FIG. 1B, the dye includes a plurality of dye particles 144. The recessed portion 142a1 and the void 142a2 are formed by a process of the dye particles absorbing the laser energy and then vaporizing. The vaporized recessed portions 142a1 show a color of white. In addition, the dye is, for example, an organic small molecule, polycyclic structure with long 7r-conjugated system to achieve longer wavelength absorption. Each dye particle 144 has various colors such as black, green, red, blue, orange, etc. The recessed portion 142a1 has a plurality of concave portions (or concave holes) that include structures similar to that of the voids 142a2. A plurality of the void is accumulated on the insulation body 141 from the first insulation surface 141s1 to form the expanded recessed portion 142a1.

As illustrated in FIG. 1C, the dye is, for example, a photo-sensitive dye. For laser marking recognition, the dye may absorb the energy of the laser beam having wavelength of 532 nanometer (nm), and thus the recessed portions 142a1 and the voids 142a2 may be formed by using the laser beam having wavelength of 532 nm. The dye has strong absorption on 532 nm to achieve good capability with laser marking wavelength. In addition, the dye has visible light region (about 400 nm to about 700 nm) absorption to achieve the contrast for laser marking recognition. Due to the absorption for visible light, the insulation body 141 has a visible light transmittance less than 50% to increase the contrast relative to the recessed portions 142a1 (namely, the first pattern P11). In an embodiment, the visible light transmittance ranges, for example, between 1% and 20%, or 20% and 50%, even greater, or even smaller. For lithography ability, the dye has a low absorbance for G-line of 436 nm, I-line of 365 nm and H-line of 405 nm, and accordingly the dye may mitigate the impact on lithography.

As illustrated in FIG. 1D, a curve C1 represents a relationship between the wavelength and the absorption coefficient for the insulation layer 140, and a curve C2 represents a relationship between the wavelength and the absorption coefficient for the dielectric layer without the dye. For laser marking recognition, the insulation layer 140 may absorb the energy of the laser beam having wavelength of 532 nm, and thus the recessed portions 142a1 and the voids 142a2 may be formed by using the laser beam having wavelength of 532 nm. The insulation layer 140 has strong absorption on 532 nm to achieve good capability with laser marking wavelength. In addition, the insulation layer 140 has visible light region absorption to achieve the contrast for laser marking recognition. For lithography ability, the insulation layer 140 has a high absorption coefficient for exposure beam of 355 nm, and accordingly the insulation layer 140 may be etched in the lithography.

As illustrated in FIG. 1B, the second RDL structure 150 may be formed on a second package surface 120s2 of the package body 120. The second RDL structure 150 includes at least one second conductive trace layer 151, at least one second conductive via layer 152 and at least one second dielectric layer 153, wherein the adjacent two second conductive trace layers 151 are separated from one of the second dielectric layers 153, and the adjacent two second conductive trace layers 151 may be electrically connected by one of the second conductive via layers 152. In addition, the second conductive trace layer 151 and the second conductive via layer 152 may be formed of, a material including, for example, copper, etc., and the second dielectric layers 153 may be formed of, a material including, for example, polyimide, etc.

As illustrated in FIG. 1B, the second RDL structure 150 and the first RDL structure 130 respectively formed on the opposite two sides of the semiconductor component 110 may balance structure of the semiconductor package 100, accordingly it may reduce the warpage of the semiconductor package 100. As long as the structures on opposite two sides of the semiconductor component 110 may be balanced, the layer number of the RDL in the first RDL structure 130 and the layer number of the RDL in the second RDL structure 150 are not limited by the present embodiment of this disclosure.

As illustrated in FIG. 1B, the conductive vias 160 electrically connect the first RDL structure 130 with the second RDL structure 150. In the present embodiment, the conductive via 160 is, for example, TIV (Through Integrated Fan-out Via). A lateral surface 160s of the conductive via 160 is covered by the package body 120 and two terminal surfaces 160e of the conductive via 160 are exposed from the package body 120. The two terminal surfaces 160e of the conductive via 160 are electrically connected to the first RDL structure 130 and the second RDL structure 150 respectively.

As illustrated in FIG. 1B, the first conductor contacts 170A are formed on the first RDL structure 130 through the insulation through-hole 143a of the insulation layer 140 and the dielectric through-hole 133a of the first dielectric layer 133. In the present embodiment, the first conductor contact 170A is, for example, pre-solder.

As illustrated in FIG. 1B, the second conductor contacts 170B are formed on the second RDL structure 150. Furthermore, the second RDL structure 150 further includes at least one second conductive bump 154 electrically connected to the bottommost second conductive via layer 152, and the second conductor contacts 170B are formed on the second conductive bumps 154 of the second RDL structure 150. In the present embodiment, the second conductor contact 170B is, for example, pre-solder.

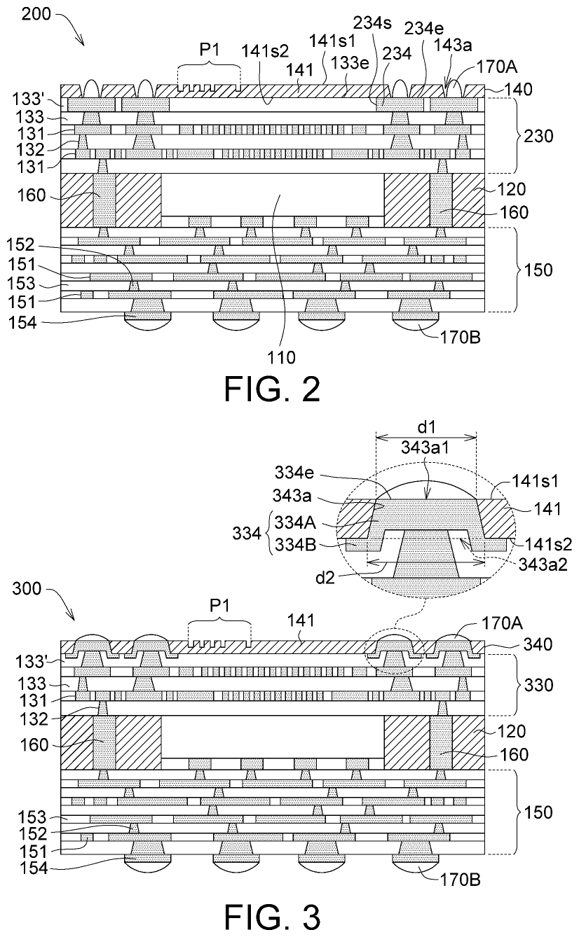

Referring to FIG. 2, FIG. 2 illustrates a schematic diagram of a cross-sectional view of the semiconductor package 200 according to another embodiment of the present disclosure. The semiconductor package 200 includes at least one semiconductor component 110, the package body 120, the first RDL structure 230, at least one conductive bump 234, the insulation layer 140, and the second RDL structure 150, at least one conductive via 160, at least one first conductor contact 170A and at least one second conductor contact 170B.

The semiconductor package 200 includes the features the same as or similar to that of the semiconductor package 100 except that, for example, the semiconductor package 200 further includes the conductive bump 234.

As illustrated in FIG. 2, the conductive bump 234 is formed between the insulation layer 140 and the first RDL structure 230. The conductive bump 234 may balance structure of the semiconductor package 200, and accordingly it reduces the warpage of the semiconductor package 200 and the IMC (Inter-Metallic Compound) cracks. In an embodiment, the conductive bump 234 has a thickness ranging 8 μm to 14 μm, for example, 8 μm, 9 μm, 10 μm, 11 μm, 12 μm, 13 μm, 14 μm, etc.

As illustrated in FIG. 2, the conductive bump 234 has a lateral surface 234s covered by one of the outermost first dielectric layers 133′ and a terminal surface 234e exposed from the outermost first dielectric layers 133′. The first conductor contact 170A is formed on the terminal surface 234e of the exposed conductive bump 234 through the insulation through-hole 143a of the insulation layer 140. In an embodiment, the insulation layer 140 has the first insulation surface 141s1 and a second insulation surface 141s2 opposite to the first insulation surface 141s1. The outermost first dielectric layers 133′ has a terminal surface 133e, and the terminal surface 234e and the terminal surface 133e are flush with each other.

Referring to FIG. 3, FIG. 3 illustrates a schematic diagram of a cross-sectional view of the semiconductor package 300 according to another embodiment of the present disclosure. The semiconductor package 300 includes at least one semiconductor component 110, the package body 120, the first RDL structure 330, at least one conductive bump 334, the insulation layer 340, and the second RDL structure 150, at least one conductive via 160, at least one first conductor contact 170A and at least one second conductor contact 170B.

The semiconductor package 300 includes the features the same as or similar to that of the semiconductor package 100 except that, for example, the semiconductor package 300 further includes the conductive bump 334 and the insulation layer 340 has structures different from the insulation layer 140.

As illustrated in FIG. 3, the insulation layer 340 is formed on the first RDL structure 330 and includes the insulation body 141, a plurality of recessed portions 142a1, a plurality of voids 142a2 and at least one insulation through-hole 343a. The insulation body 141 has the first insulation surface 141s1, wherein the recessed portions 142a1 (not illustrated) are recessed with respect to the first insulation surface 141s1 and form the pattern P1, and the voids 142a2 (not illustrated) are embedded in the insulation body 141. The insulation through-hole 343a passes through the insulation body 141, exposes a first opening 343a1 from the first insulation surface 141s1, exposes a second opening 343a2 from the second insulation surface 141s2, the first opening 143a1 has a first diameter d1, the second opening 343a2 has a second diameter d2, and the first diameter d1 is smaller than the second diameter d2. In an embodiment, an inner diameter of the insulation through-hole 343a gradually shrinks in a direction from the second opening 343a2 toward the first opening 343a1.

As illustrated in FIG. 3, the conductive bump 334 is formed on the insulation through-hole 343a and has a terminal surface 334e. The terminal surface 334e and the first insulation surface 141s1 are flush with each other. In addition, the first conductor contacts 170A are formed on the exposed conductive bump 334 through the insulation through-hole 343a of the insulation layer 340. In addition, the conductive bump 334 includes a first portion 334A and a second portion 334B, wherein the first portion 334A is formed within the insulation through-hole 343a and the second portion 334B covers the second insulation surface 141s2.

As illustrated in FIG. 3, the first dielectric layer 133′ of the first RDL structure 330 covers the conductive bump 334 and the first conductive via layer 132 of the first RDL structure 330.

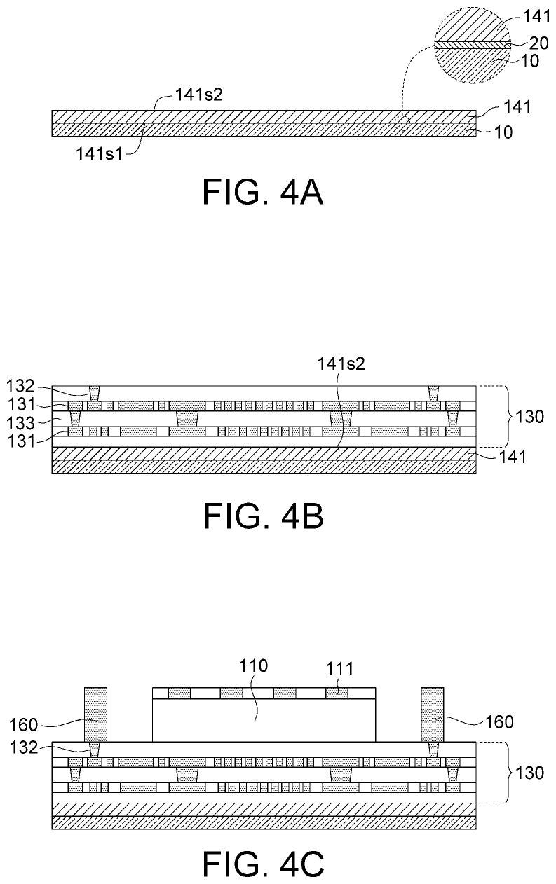

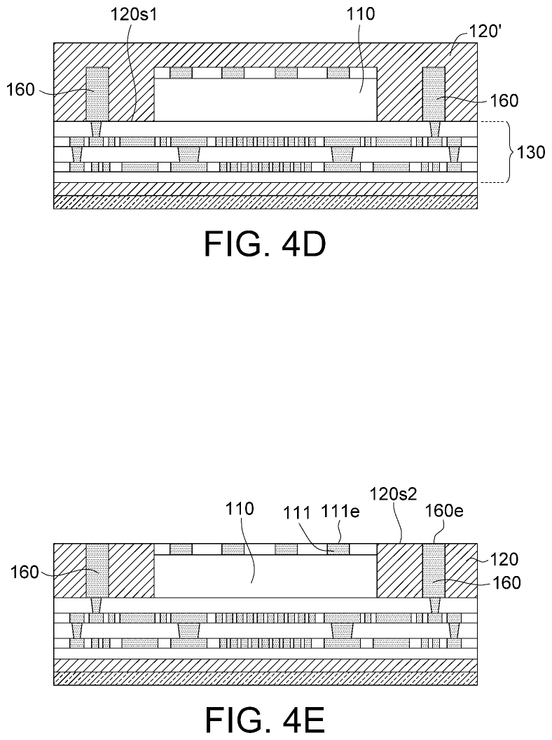

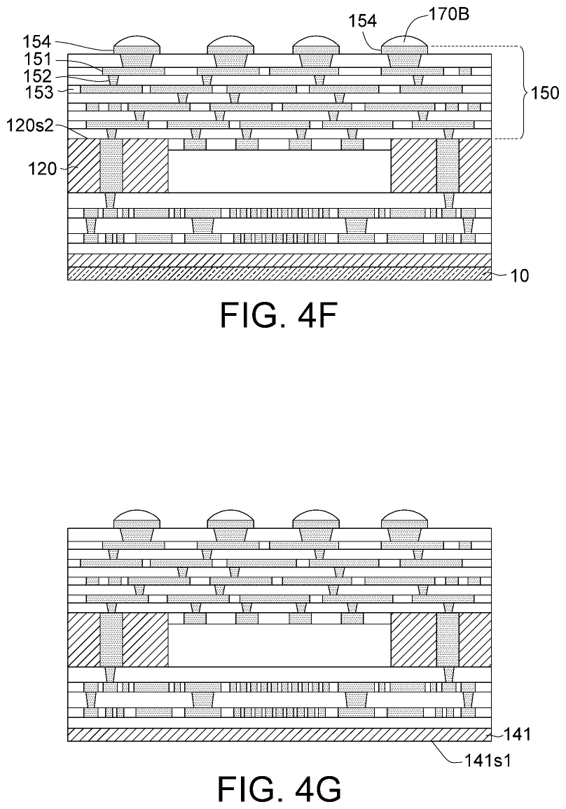

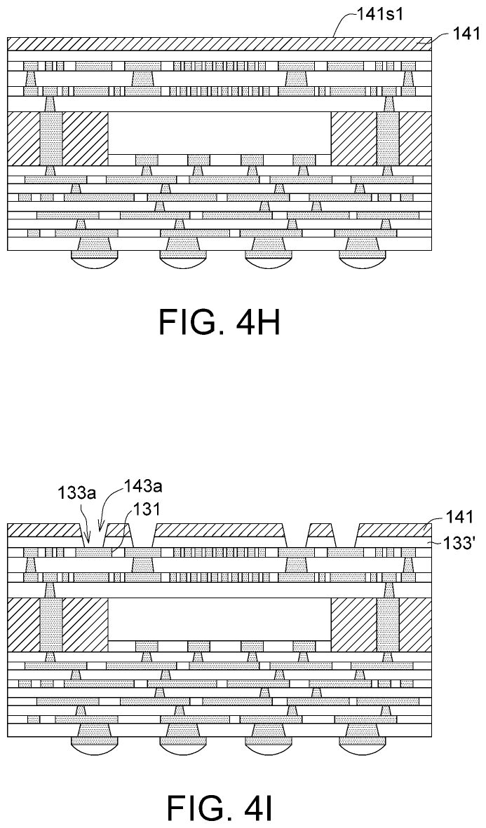

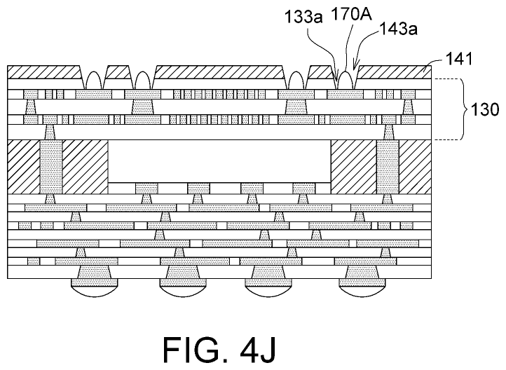

Referring to FIGS. 4A to 4J, FIGS. 4A to 4J illustrate schematic diagrams of a manufacturing method of the semiconductor package 100 of FIG. 1B.

As illustrated in FIG. 4A, the insulation body 141 is formed on a carrier 10 through a release layer 20, wherein the release layer 20 is, for example, a LTHC (Light-To-Heat-Conversion Release Coating). The insulation body 141 is formed by using, for example, spin coating, etc. The insulation body 141 is formed of a material including, for example, polyimide, Benzocyclobutene, Polybenzoxazole or epoxy. The insulation body 141 has the first insulation surface 141s1 and the second insulation surface 141s2 opposite to the first insulation surface 141s1, wherein the first insulation surface 141s1 faces the carrier 10.

As illustrated in FIG. 4B, the first RDL structure 130 is formed on the second insulation surface 141s2 of the insulation body 141, wherein the first RDL structure 130 includes at least one first conductive trace layer 131, at least one first conductive via layer 132 and at least one first dielectric layer 133. The first conductive trace layer 131 and the first conductive trace layer 131 may be formed by using, for example, electroplating, etc., and the first dielectric layer 133 may be formed by using, for example, lithography, etc.

As illustrated in FIG. 4C, at least one semiconductor component 110 and at least one conductive via 160 electrically connected to the first conductive via layer 132 are disposed on the first RDL structure 130. The semiconductor component 110 includes a plurality of conductive contact 111, and the conductive contact 111 faces up. The conductive via 160 is formed by using, for example, electroplating, etc., and the semiconductor component 110 is disposed on the first RDL structure 130 by using, for example, a SMT (Surface mount technology).

As illustrated in FIG. 4D, the package body material 120′ encapsulating the conductive via 160 and the semiconductor component 110 is formed on the first RDL structure 130 by using, for example, a compression molding, an injection molding or a transfer molding. The package body material 120′ has the first package surface 120s1 disposed on the first RDL structure 130. The package body material 120 may be formed of a molding material including, for example, a Novolac-based resin, an epoxy-based resin, a silicone-based resin, or another suitable encapsulant. Suitable fillers also may be included, such as powdered SiO2.

As illustrated in FIG. 4E, a portion of the package body material 120′ is removed by using, for example, a CMP (Chemical-Mechanical Planarization), and a remaining portion of the package body material 120′ form the package body 120. After the CMP, the package body 120 has the second package surface 120s2, the conductive via 160 has a terminal surface 160e, and the conductive contact 111 has a terminal surface 111e, wherein the second package surface 120s2, the terminal surface 160e and the terminal surface 111e are flush with each other.

As illustrated in FIG. 4F, the second RDL structure 150 is formed on the second package surface 120s2 of the package body 120, wherein the second RDL structure 150 includes at least one second conductive trace layer 151, at least one second conductive via layer 152, at least one second dielectric layer 153 and at least one second conductive bump 154. The second conductive trace layer 151, the second conductive via layer 152 and the second conductive bump 154 are formed by using, for example, electroplating, etc., and the second dielectric layer 153 is formed by using, for example, lithography, etc.

As illustrated in FIG. 4F, at least one second conductor contact 170B is formed on the second RDL structure 150. Furthermore, the second conductor contact 170B is formed on the second conductive bump 154 by using, for example, printing.

As illustrated in FIG. 4G, the carrier 10 of FIG. 4F is removed with the release layer 20 from the first RDL structure 130 to expose the first insulation surface 141s1 of the insulation body 141.

As illustrated in FIG. 4H, the structure of FIG. 4G is inverted to make the insulation body 141 face up.

As illustrated in FIG. 4I, at least one insulation through-hole 143a passing through the insulation body 141 and at least one dielectric through-hole 133a passing through the outermost first dielectric layer 133′ of the first RDL structure 130 are formed by using, for example, laser drilling. The insulation through-hole 143a and the dielectric through-hole 133a overlap to expose a pad or a bump of the first conductive trace layer 131.

As illustrated in FIG. 4J, at least one first conductor contact 170A is formed on the exposed first conductive trace layer 131 through the insulation through-hole 143a and the dielectric through-hole 133a by using, for example, printing.

Then, a plurality of the recessed portions 142a1 and a plurality of the voids 142a2 of FIG. 1B are formed on the insulation body 141 of FIG. 4J by using, for example, laser marking, wherein the recessed portions 142a1 are recessed with respect to the first insulation surface 141s1 of the insulation body 141 and form the pattern P1, and the voids 142a2 are embedded in the insulation body 141, as illustrated in FIG. 1B. In an embodiment, the recessed portions 142a1 and the voids 142a2 may be formed in the same manufacturing process.

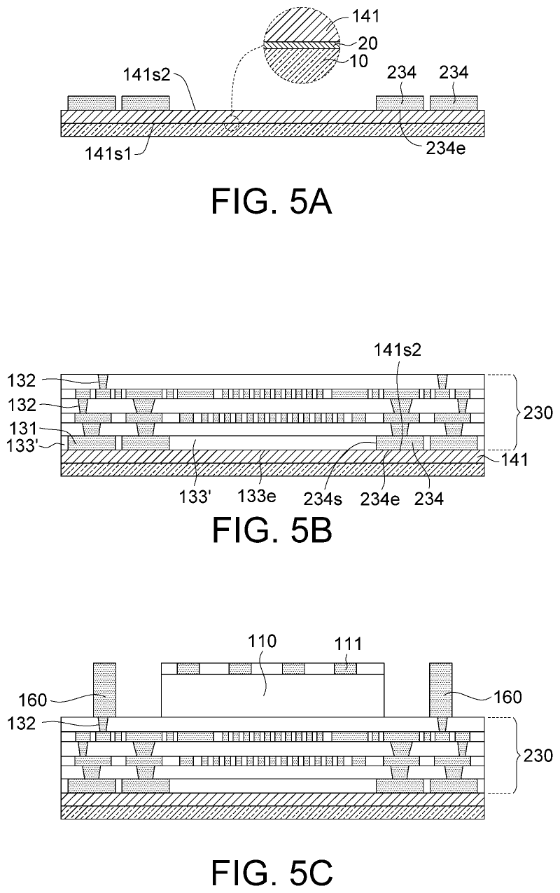

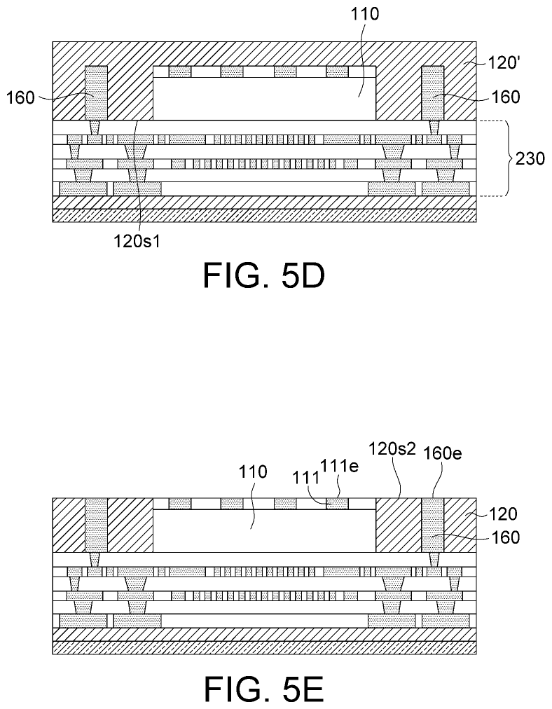

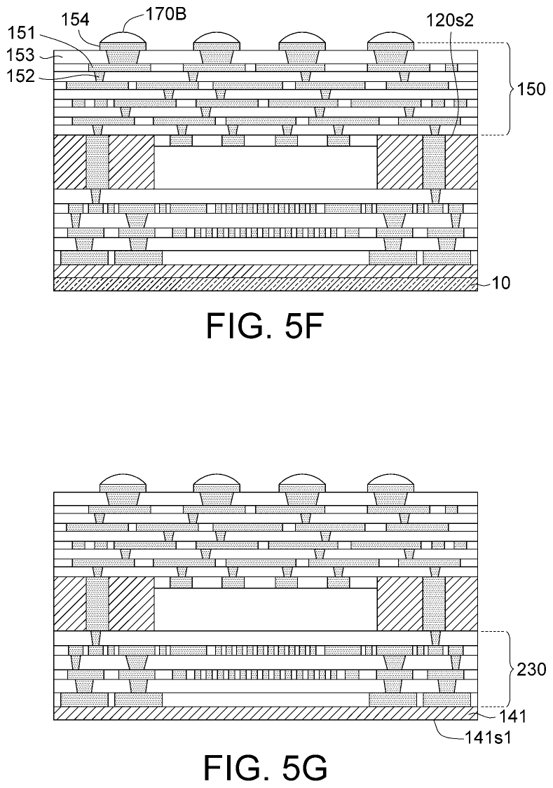

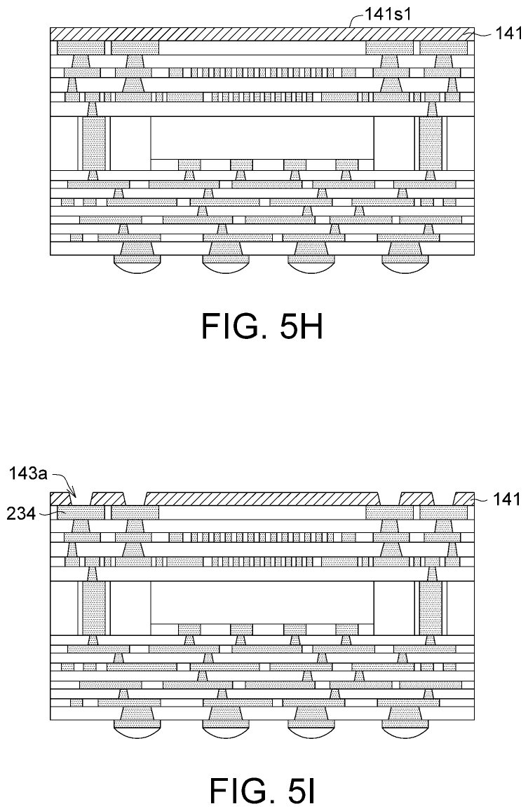

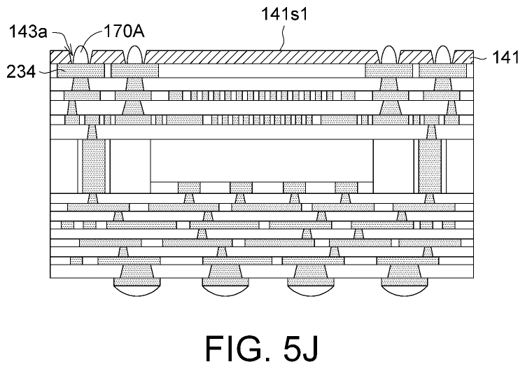

Referring to FIGS. 5A to 5J, FIGS. 5A to 5J illustrate schematic diagrams of a manufacturing method of the semiconductor package 200 of FIG. 2.

As illustrated in FIG. 5A, the insulation body 141 is formed on the carrier 10 through the release layer 20. The insulation body 141 is formed by using, for example, spin coating, etc. Then, at least one conductive bump 234 is formed on the insulation body 141 by using, for example, electroplating, etc. The insulation body 141 has the first insulation surface 141s1 and the second insulation surface 141s2 opposite to the first insulation surface 141s1, wherein the first insulation surface 141s1 faces the carrier 10. The conductive bump 234 has the terminal surface 234e disposed on the second insulation surface 141s2.

As illustrated in FIG. 5B, the first RDL structure 230 is formed on the second insulation surface 141s2 of the insulation body 141, wherein the first RDL structure 230 includes at least one first conductive trace layer 131, at least one first conductive via layer 132 and at least one first dielectric layer 133. The first conductive trace layer 131 and the first conductive trace layer 131 are formed by using, for example, electroplating, etc., and the first dielectric layer 133 is formed by using, for example, lithography, etc. In addition, the outermost first dielectric layers 133′ disposed on the insulation body 141 covers the lateral surface 234s of the conductive bump 234. The first dielectric layers 133′ has a terminal surface 133e, and the terminal surface 133e and the terminal surface 234e are flush with each other (for example, coplanar).

As illustrated in FIG. 5C, at least one semiconductor component 110 and at least one conductive via 160 electrically connected to the first conductive via layer 132 are disposed on the first RDL structure 230. The semiconductor component 110 includes a plurality of conductive contact 111, and the conductive contact 111 faces up. The conductive via 160 is formed by using, for example, electroplating, etc., and the semiconductor component 110 is disposed on the first RDL structure 230 by using, for example, a SMT.

As illustrated in FIG. 5D, the package body material 120′ encapsulating the conductive via 160 and the semiconductor component 110 is formed by using, for example, by using, for example, a compression molding, an injection molding or a transfer molding. The package body material 120′ has the first package surface 120s1 disposed on the first RDL structure 230.

As illustrated in FIG. 5E, a portion of the package body material 120′ is removed by using, for example, a CMP, and a remaining portion of the package body material 120′ form the package body 120. After the CMP, the package body 120 has the second package surface 120s2, the conductive via 160 has the terminal surface 160e, and the conductive contact 111 has the terminal surface 111e, wherein the terminal surface 120s2, the terminal surface 160e and the terminal surface 111e are flush with each other.

As illustrated in FIG. 5F, the second RDL structure 150 is formed on the second package surface 120s2 of the package body 120, wherein the second RDL structure 150 includes at least one second conductive trace layer 151, at least one second conductive via layer 152, at least one second dielectric layer 153 and at least one second conductive bump 154. The second conductive trace layer 151, the second conductive via layer 152 and the second conductive bump 154 are formed by using, for example, electroplating, etc., and the second dielectric layer 153 is formed by using, for example, lithography, etc.

As illustrated in FIG. 5F, at least one second conductor contact 170B is formed on the second RDL structure 150. Furthermore, the second conductor contact 170B is formed on the second conductive bump 154 by using, for example, printing.

As illustrated in FIG. 5G, the carrier 10 of FIG. 5F is removed with the release layer 20 from the first RDL structure 230 to expose the first insulation surface 141s1 of the insulation body 141.

As illustrated in FIG. 5H, the structure of FIG. 5G is inverted to make the insulation body 141 face up.

As illustrated in FIG. 5I, at least one insulation through-hole 143a passing through the insulation body 141 are formed by using, for example, laser drilling. The insulation through-hole 143a exposes the conductive bump 234.

As illustrated in FIG. 5J, at least one first conductor contact 170A is formed on the exposed conductive bump 234 through the insulation through-hole 143a by using, for example, printing.

Then, a plurality of the recessed portions 142a1 and a plurality of the voids 142a2 of FIG. 1B are formed on the insulation body 141 of FIG. 5I by using, for example, laser marking, wherein the recessed portions 142a1 are recessed with respect to the first insulation surface 141s1 of the insulation body 141 and form the pattern P1, and the voids 142a2 are embedded in the insulation body 141, as illustrated in FIG. 1B.

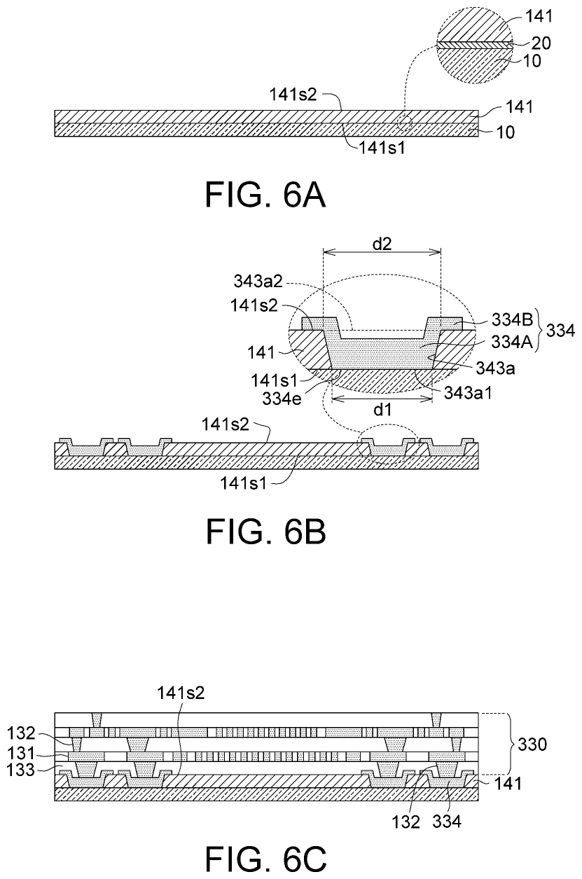

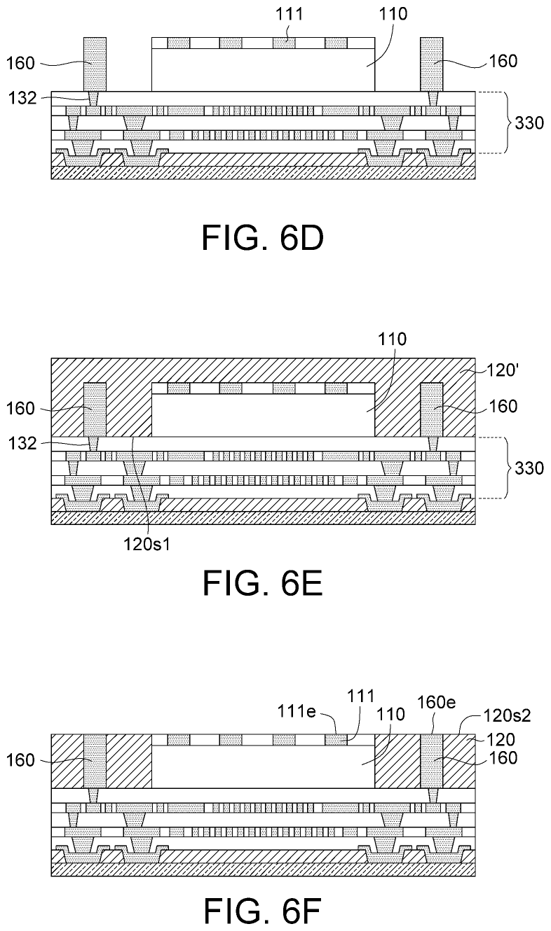

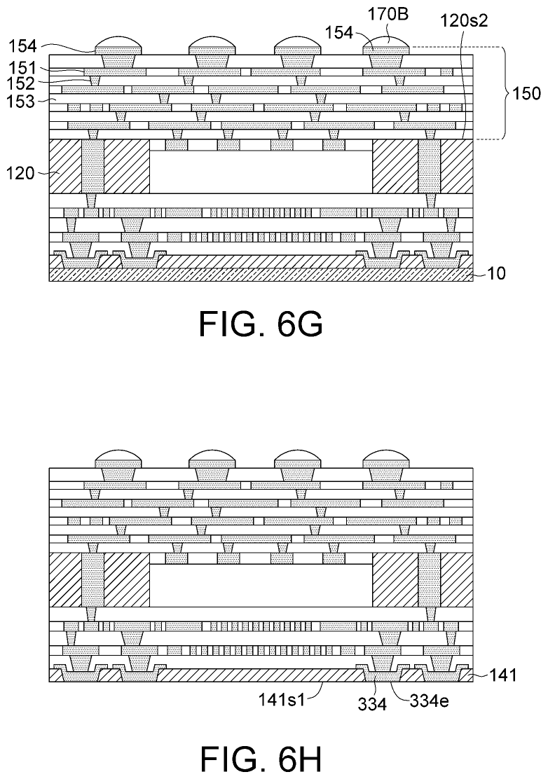

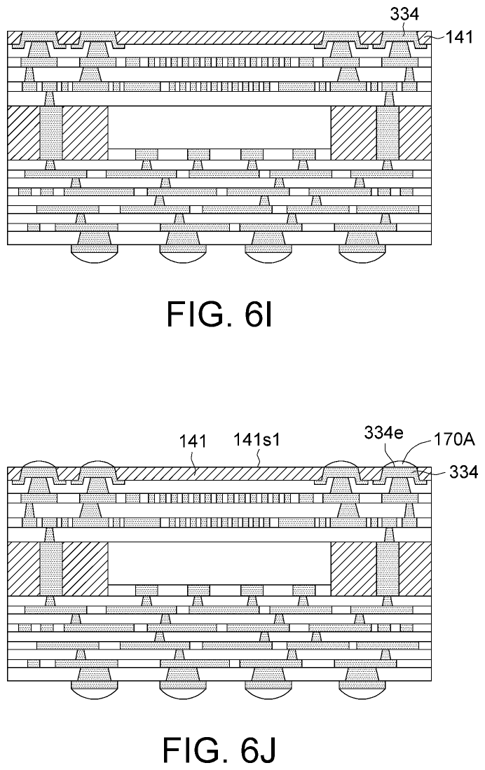

Referring to FIGS. 6A to 6J, FIGS. 6A to 6J illustrate schematic diagrams of a manufacturing method of the semiconductor package 300 of FIG. 3.

As illustrated in FIG. 6A, the insulation body 141 is formed on the carrier 10 through the release layer 20. The insulation body 141 is formed by using, for example, spin coating, etc. The insulation body 141 has the first insulation surface 141s1 and the second insulation surface 141s2 opposite to the first insulation surface 141s1, wherein the first insulation surface 141s1 faces the carrier 10.

As illustrated in FIG. 6B, at least one insulation through-hole 343a passing through the insulation body 141 is formed by using, for example, lithography, etc. The insulation through-hole 343a exposes the first opening 343a1 from the first insulation surface 141s1, exposes the second opening 343a2 from the second insulation surface 141s2, the first opening 143a1 has the first diameter d1, the second opening 343a2 has the second diameter d2, and the first diameter d1 is smaller than the second diameter d2. In an embodiment, the inner diameter of the insulation through-hole 343a gradually shrinks in a direction from the second opening 343a2 toward the first opening 343a1.

As illustrated in FIG. 6B, at least one conductive bump 334 is formed within the insulation through-hole 343a by using, for example, electroplating, etc., wherein the conductive bump 334 includes the first portion 334A and the second portion 334B, wherein the first portion 334A is formed within the insulation through-hole 343a and the second portion 334B covers the second insulation surface 141s2. In addition, the conductive bump 334 has the terminal surface 334e, and the terminal surface 334e and the first insulation surface 141s1 are flush with each other.

As illustrated in FIG. 6C, the first RDL structure 330 is formed on the second insulation surface 141s2 of the insulation body 141, wherein the first RDL structure 330 includes at least one first conductive trace layer 131, at least one first conductive via layer 132 and at least one first dielectric layer 133. The first conductive via layer 132 is electrically connected to the conductive bump 334. The first conductive trace layer 131 and the first conductive trace layer 131 are formed by using, for example, electroplating, etc., and the first dielectric layer 133 is formed by using, for example, lithography, etc.

As illustrated in FIG. 6D, at least one semiconductor component 110 and at least one conductive via 160 electrically connected to the first conductive via layer 132 are disposed on the first RDL structure 330. The semiconductor component 110 includes a plurality of conductive contact 111, and the conductive contact 111 faces up. The conductive via 160 is formed by using, for example, electroplating, etc., and the semiconductor component 110 is disposed on the first RDL structure 330 by using, for example, a SMT.

As illustrated in FIG. 6E, the package body material 120′ encapsulating the conductive via 160 and the semiconductor component 110 is formed by using, for example, a compression molding, an injection molding or a transfer molding. The package body material 120′ has the first package surface 120s1 disposed on the first RDL structure 330.

As illustrated in FIG. 6F, a portion of the package body material 120′ is removed by using, for example, a CMP, and a remaining portion of the package body material 120′ form the package body 120. After the CMP, the package body 120 has the second package surface 120s2, the conductive via 160 has the terminal surface 160e, and the conductive contact 111 has the terminal surface 111e, wherein the second package surface 120s2, the terminal surface 160e and the terminal surface 111e are flush with each other.

As illustrated in FIG. 6G, the second RDL structure 150 is formed on the second package surface 120s2 of the package body 120, wherein the second RDL structure 150 includes at least one second conductive trace layer 151, at least one second conductive via layer 152, at least one second dielectric layer 153 and at least one second conductive bump 154. The second conductive trace layer 151, the second conductive via layer 152 and the second conductive bump 154 are formed by using, for example, electroplating, etc., and the second dielectric layer 153 is formed by using, for example, lithography, etc.

As illustrated in FIG. 6G, at least one second conductor contact 170B is formed on the second RDL structure 150. Furthermore, the second conductor contact 170B is formed on the second conductive bump 154 by using, for example, printing.

As illustrated in FIG. 6H, the carrier 10 of FIG. 6G is removed with the release layer 20 from the first RDL structure 330 to expose the terminal surface 334e of the conductive bump 334 and the first insulation surface 141s1 of the insulation body 141.

As illustrated in FIG. 6I, the structure of FIG. 6H is inverted to make the conductive bump 334 and the insulation body 141 faces up.

As illustrated in FIG. 6J, at least one first conductor contact 170A is formed on the terminal surface 334e of the conductive bump 334 by using, for example, printing.

Then, a plurality of the recessed portions 142a1 and a plurality of the voids 142a2 of FIG. 1B are formed on the insulation body 141 of FIG. 6J by using, for example, laser marking, wherein the recessed portions 142a1 are recessed with respect to the first insulation surface 141s1 of the insulation body 141 and form the pattern P1, and the voids 142a2 are embedded in the insulation body 141, as illustrated in FIG. 1B.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor package at least includes an insulation layer formed on a RDL structure and including an insulation body, a plurality of recessed portions and a plurality of voids, wherein the insulation body has a first insulation surface, the recessed portions are recessed with respect to the first insulation surface and form a pattern, and the voids are embedded in the insulation body. Accordingly, the pattern is highly recognizable, and the semiconductor package may pass the visual inspection, data code inspection and/or OCR inspection via an optical defect inspection device.

Example embodiment 1: a semiconductor package includes a semiconductor component, a package body, a first RDL structure and an insulation layer. The package body surrounds the semiconductor component and has a first package surface. The first RDL structure is formed on the first package surface of the package body. The insulation layer is formed on the first RDL structure and including an insulation body, a plurality of recessed portions and a plurality of voids, wherein the insulation body has a first insulation surface, the recessed portions are recessed with respect to the first insulation surface and form a pattern, and the voids are embedded in the insulation body.

Example embodiment 2 based on Example embodiment 1: the package body has a second package surface opposite to the first package surface, the semiconductor package further includes a second RDL structure, the second RDL structure is formed on the second package surface of the package body.

Example embodiment 3 based on Example embodiment 2: the semiconductor package further includes a plurality of conductive vias connecting the first RDL structure with the second RDL structure, wherein the package body surrounds the conductive vias.

Example embodiment 4 based on Example embodiment 1: the insulation layer further includes a dye doped in the insulation body, the dye is organic molecule, and the dye is a photo-sensitive dye.

Example embodiment 5 based on Example embodiment 4: the insulation body is formed of a material including polyimide (PI), Benzocyclobutene (BCB), Polybenzoxazole (BPO) or epoxy.

Example embodiment 6 based on Example embodiment 1: the insulation layer further has an insulation through-hole and a second insulation surface opposite to the first insulation surface; the insulation through-hole passes through the insulation body, exposes a first opening from the first insulation surface, exposes a second opening from the second insulation surface, the first opening has a first diameter, the second opening has a second diameter, and the first diameter is smaller than the second diameter.

Example embodiment 7 based on Example embodiment 6: the semiconductor package further includes a conductive bump formed on the insulation through-hole and having a terminal surface, wherein the terminal surface and the first insulation surface are flush with each other.

Example embodiment 8 based on Example embodiment 1: the semiconductor package further includes a conductive bump formed between the insulation layer and the first RDL structure, wherein a portion of the conductive bump is embedded in the insulation layer, and another portion of the conductive bump is formed on a surface of the insulation layer.

Example embodiment 9 based on Example embodiment 1: each recessed portion has a color of white.

Example embodiment 10: a semiconductor package includes a semiconductor component, a package body, a first RDL structure and an insulation layer, wherein the package body surrounds the semiconductor component and has a first package surface, the first RDL structure is formed on the first package surface of the package body, and the insulation layer is formed on the first RDL structure and includes an insulation body and a plurality of recessed portions, the insulation body has a first insulation surface and a visible light transmittance, the recessed portions are recessed with respect to the first insulation surface and form a pattern, and the visible light transmittance is less than 50%.

Example embodiment 11 based on Example embodiment 10: the visible light transmittance ranges between 20% and 50%.

Example embodiment 12 based on Example embodiment 10: the insulation layer further includes a dye doped in the insulation body, the dye is organic molecule, and the dye is a photo-sensitive dye.

Example embodiment 13 based on Example embodiment 12: the insulation body is formed of a material including polyimide, Benzocyclobutene, Polybenzoxazole or epoxy.

Example embodiment 14: a manufacturing method of a semiconductor package, includes the following steps: forming an insulation body on a carrier, wherein the insulation body has a first insulation surface facing the carrier; forming a first RDL structure formed on the insulation body; disposing a semiconductor component on the first RDL structure; forming a package body to surround the semiconductor component, wherein the package body has a first package surface disposed on the first RDL structure; and forming a plurality of recessed portions and a plurality of voids on the insulation body, wherein the recessed portions are recessed with respect to a first insulation surface of the insulation body and form a pattern, and the voids are embedded in the insulation body.

Example embodiment 15 based on Example embodiment 14: the package body has a second package surface opposite to the first package surface; the manufacturing method further includes: forming a second RDL structure on the second package surface of the package body.

Example embodiment 16 based on Example embodiment 15: the manufacturing method further includes: forming a plurality of conductive vias on the first RDL structure; in forming the package body to surround the semiconductor component, the package body surrounds the conductive vias; in forming the second RDL structure on the second package surface of the package body, the conductive vias are connected to the second RDL structure.

Example embodiment 17 based on Example embodiment 14: the insulation layer further includes a dye doped in the insulation body; in forming the plurality of the recessed portions and the plurality of the voids, in forming the plurality of recessed portions and the plurality of voids on the insulation body, the plurality of the recessed portions and the plurality of the voids fare formed by a laser marking process of the dye absorbing the laser energy and then vaporizing.

Example embodiment 18 based on Example embodiment 14: the forming the insulation layer on the carrier includes: forming a conductive bump on the insulation layer; and in forming the first RDL structure formed on the insulation layer, the conductive bump is formed between the insulation layer and the first RDL structure.

Example embodiment 19 based on Example embodiment 14: the insulation layer further has a second insulation surface opposite to the first insulation surface, and forming the insulation layer on the carrier includes: forming an insulation through-hole to pass through the insulation body, wherein the insulation through-hole exposes a first opening from the first insulation surface, exposes a second opening from the second insulation surface, the first opening has a first diameter, the second opening has a second diameter, and the first diameter is smaller than the second diameter.

Example embodiment 20 based on Example embodiment 19: the manufacturing method further includes: forming a conductive bump on the insulation through-hole, wherein the conductive bump has a terminal surface, and the terminal surface and the first insulation surface are flush with each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a semiconductor component;
a package body surrounding the semiconductor component and having a first package surface;
a first redistribution layer (RDL) structure formed on the first package surface of the package body; and
an insulation layer formed on the first RDL structure and comprising an insulation body, a plurality of recessed portions and a plurality of voids, wherein the insulation body has a first insulation surface, the recessed portions are recessed with respect to the first insulation surface and form a pattern, and the voids are embedded in the insulation body.

2. The semiconductor package as claimed in claim 1, wherein the package body has a second package surface opposite to the first package surface, the semiconductor package further comprises:
a second RDL structure formed on the second package surface of the package body.

3. The semiconductor package as claimed in claim 2, further comprises:
a plurality of conductive vias connecting the first RDL structure with the second RDL structure;
wherein the package body surrounds the conductive vias.

4. The semiconductor package as claimed in claim 1, wherein the insulation layer further comprises a dye doped in the insulation body, the dye is organic molecule, and the dye is a photo-sensitive dye.

5. The semiconductor package as claimed in claim 4, wherein the insulation body is formed of a material comprising polyimide (PI), Benzocyclobutene (BCB), Polybenzoxazole (BPO) or epoxy.

6. The semiconductor package as claimed in claim 1, wherein the insulation layer further has an insulation through-hole and a second insulation surface opposite to the first insulation surface; the insulation through-hole passes through the insulation body, exposes a first opening from the first insulation surface, exposes a second opening from the second insulation surface, the first opening has a first diameter, the second opening has a second diameter, and the first diameter is smaller than the second diameter.

7. The semiconductor package as claimed in claim 6, further comprises:
a conductive bump formed on the insulation through-hole and having a terminal surface;
wherein the terminal surface and the first insulation surface are flush with each other.

8. The semiconductor package as claimed in claim 1, further comprises:
a conductive bump formed between the insulation layer and the first RDL structure;
wherein a portion of the conductive bump is embedded in the insulation layer, and another portion of the conductive bump is formed on a surface of the insulation layer.

9. The semiconductor package as claimed in claim 1, wherein each recessed portion has a color of white.

10. A semiconductor package, comprising:
a semiconductor component;
a package body surrounding the semiconductor component and having a first package surface;
a first RDL structure formed on the first package surface of the package body; and
an insulation layer formed on the first RDL structure and comprising an insulation body, a plurality of recessed portions, wherein the insulation body has a first insulation surface and a visible light transmittance, the recessed portions are recessed with respect to the first insulation surface and form a pattern, and the visible light transmittance is less than 50%.

11. The semiconductor package as claimed in claim 10, wherein the visible light transmittance ranges between 20% and 50%.

12. The semiconductor package as claimed in claim 10, wherein the insulation layer further comprises a dye doped in the insulation body, the dye is organic molecule, and the dye is a photo-sensitive dye.

13. The semiconductor package as claimed in claim 12, wherein the insulation body is formed of a material comprising polyimide, Benzocyclobutene, Polybenzoxazole or epoxy.

14. A manufacturing method of a semiconductor package, comprising:
forming an insulation body on a carrier, wherein the insulation body has a first insulation surface facing the carrier;
forming a first RDL structure formed on the insulation body;
disposing a semiconductor component on the first RDL structure;
forming a package body to surround the semiconductor component, wherein the package body has a first package surface disposed on the first RDL structure; and
forming a plurality of recessed portions and a plurality of voids on the insulation body, wherein the recessed portions are recessed with respect to a first insulation surface of the insulation body and form a pattern, and the voids are embedded in the insulation body.

15. The manufacturing method as claimed in claim 14, wherein the package body has a second package surface opposite to the first package surface, the manufacturing method further comprises:
forming a second RDL structure on the second package surface of the package body.

16. The manufacturing method as claimed in claim 15, further comprises:
forming a plurality of conductive vias on the first RDL structure;
in forming the package body to surround the semiconductor component, the package body surrounds the conductive vias; and
in forming the second RDL structure on the second package surface of the package body, the conductive vias are connected to the second RDL structure.

17. The manufacturing method as claimed in claim 14, wherein the insulation layer further comprises a dye doped in the insulation body; in forming the plurality of the recessed portions and the plurality of the voids, in forming the plurality of recessed portions and the plurality of voids on the insulation body, the plurality of the recessed portions and the plurality of the voids fare formed by a laser marking process of the dye absorbing the laser energy and then vaporizing.

18. The manufacturing method as claimed in claim 14, wherein forming the insulation layer on the carrier comprises:
forming a conductive bump on the insulation layer; and
in forming the first RDL structure formed on the insulation layer, the conductive bump is formed between the insulation layer and the first RDL structure.

19. The manufacturing method as claimed in claim 14, wherein the insulation layer further has a second insulation surface opposite to the first insulation surface, and forming the insulation layer on the carrier comprises:
forming an insulation through-hole to pass through the insulation body, wherein the insulation through-hole exposes a first opening from the first insulation surface, exposes a second opening from the second insulation surface, the first opening has a first diameter, the second opening has a second diameter, and the first diameter is smaller than the second diameter.

20. The manufacturing method as claimed in claim 19, further comprises:
forming a conductive bump on the insulation through-hole, wherein the conductive bump has a terminal surface, and the terminal surface and the first insulation surface are flush with each other.
